(19) United States
(12) Patent Application Publication
(10) Pub. No.: US 2004/0077158 A1
(43) Pub. Date: Apr. 22, 2004

(54) Method of manufacturing semiconductor device through salicide process

(76) Inventors: Hyeon-Ill Um, Sungnam-City (KR); Hye-Jeong Park, Seoul (KR); Kyeong-Mo Koo, Yongin-City (KR)

Correspondence Address: VOLENTINE FRANCOS, P.L.L.C., Suite 150, 12200 Sunrise Valley Drive, Reston, VA, 20191, US

(21) Appl. No.: 10/457,449

(22) Filed: Jun. 10, 2003

(30) Foreign Application Priority Data
Oct. 17, 2002 (KR) 2002-63567

(51) Int. Cl. H01L 21/28

(52) U.S. Cl. 438/582

(57) ABSTRACT

The method of fabricating a semiconductor device through a salicide process includes the steps of forming a gate electrode and source/drain regions on a semiconductor substrate, and performing only a wet etching; sequentially, entirely, forming a high melting point metal film and a capping film; forming a mono silicide film on the gate electrode and the source/drain regions through a first heat process, and removing the high melting point metal film and the capping film of a region excepting of a region where the mono silicide film is formed; and forming the di-silicide film through a second heat process.

### CROSS REFERENCES TO RELATED APPLICATIONS

This application claims priority under 35 U.S.C. § 119 from Korean Patent Application No. 2002-0063567, filed on Oct. 17, 2002, the contents of which are hereby incorporated by reference in their entirety for all purposes as if fully set forth herein.

### BACKGROUND AND SUMMARY

1. Technical Field

The present invention relates to a semiconductor device fabricating method, and more particularly, to a semiconductor device fabricating method using a salicide process of forming a silicide film as a low resistance material.

2. Description

A tendency to a gradually increased density of a semiconductor device brings about a reduction of a line width in a gate electrode of a transistor. This causes the resistance of the gate electrode to be significant. Furthermore, this causes an increase in the resistance of the source/drain regions as impurity regions of the transistor. Such an increase in resistance of the gate electrode and the source/drain regions negatively influences the operation of the semiconductor device.

Thus, a reduction of the resistance is required, and a salicide (self-align silicide) process of forming a silicide film of a low resistance material on upper parts of the gate electrode and the source/drain regions is being utilized widely to achieve that reduction in resistance.

In general, the salicide process involves forming a high-melting-point metal film on an entire surface of a semiconductor substrate having a gate electrode and source/drain regions, and then, performing a heat-process, and forming a silicide film only on upper parts of the gate electrode and the source/drain regions.

Such a salicide process mainly uses cobalt (Co). Cobalt is metal having low inherent resistance, proper for the salicide process, and is capable of being processed in forming a shallow junction part and in low temperature. To utilize cobalt in the silicide process, a wet etching and an RF sputtering etching process, as a cleaning process, are performed before a deposition of the cobalt. These wet etching and RF sputtering etching processes are executed to remove the natural oxide film formed on the gate electrode and the source/drain on which the cobalt will be deposited.

However, in such a process, particles can be caused, due to a movement between a chamber performing the wet etching and a chamber performing the RF sputtering etching process. Furthermore, residuals generated in the midst of the RF sputtering etching process can be re-sputtered to thus cause particles.

Thus, such particles can be stuck to an entire surface of the semiconductor substrate having the gate electrode and the source/drain regions, which causes an inferior result such as a void or a pit on a cobalt silicide film after the salicide process, and further causes a difficulty in forming the cobalt silicide film with a desired thickness.

Therefore, it would be desirable to provide a method of fabricating a semiconductor device through a salicide process, so as to restrain an occurrence of particles and prevent an inferior result in forming a cobalt silicide film, and to form the cobalt silicide film with a desired thickness.

It would also be desirable to provide a method of fabricating a semiconductor device through a salicide process, in which a cobalt silicide film can be formed with a desired thickness more stably.

In accordance with one aspect of the present invention, a method of fabricating a semiconductor device through a salicide process comprises forming a gate electrode and source/drain regions on a semiconductor substrate, and performing only a wet etching; sequentially and entirely, forming a high melting point metal film and a capping film; forming a mono silicide film on the gate electrode and the source/drain regions through a first heat process, and removing the high melting point metal film and the capping, except on a region where the mono silicide film is formed; and forming a di-silicide film through a second heat process.

Herewith, the wet etching is executed to eliminate a natural oxide film formed on the gate electrode and the source/drain regions, and is preferably performed for about 200˜300 seconds. Beneficially, the capping film is formed as a Ti-rich TiN film, abundant in titanium. The high melting point metal film is formed beneficially as a cobalt film. The first heat process is executed through an RTS process at a low temperature of about 450˜500° C. The second heat process is executed through the RTS process at high temperature of about 750˜900° C. Removing the high melting point metal film and the capping film, except on a region where the mono silicide film is formed, is beneficially executed through an etching.

In accordance with another aspect of the present invention, a method of fabricating a semiconductor device through a salicide process includes performing only a wet etching on a gate electrode and source/drain regions formed on a semiconductor substrate for about 200˜300 seconds in a previous process of forming a silicide film.

In accordance with a still another aspect of the present invention, the method of fabricating a semiconductor device through a salicide process includes forming a capping film on the high melting point metal film, in the salicide process of forming a high melting point metal film on an entire face of a semiconductor substrate having a gate electrode and source/drain regions, and then, performing a heat process, and of forming a silicide film only on the gate electrode and the source/drain regions.

### BRIEF DESCRIPTION OF THE DRAWINGS

The above and other objects and features of the present invention will become apparent from the following description of preferred embodiments taken in conjunction with the accompanying drawings, in which:

FIG. 1 shows a semiconductor device after initial steps of a fabrication method using a salicide process;

FIG. 2 shows a semiconductor device in a second stage of a fabrication method using a salicide process;

FIG. 3 shows a semiconductor device in a third stage of a fabrication method using a salicide process;

FIG. 4 shows a semiconductor device in a fourth stage of a fabrication method using a salicide process.

### DETAILED DESCRIPTION

Hereinafter, preferred embodiments of the present invention will be described in detail referring to the accompanied drawings.

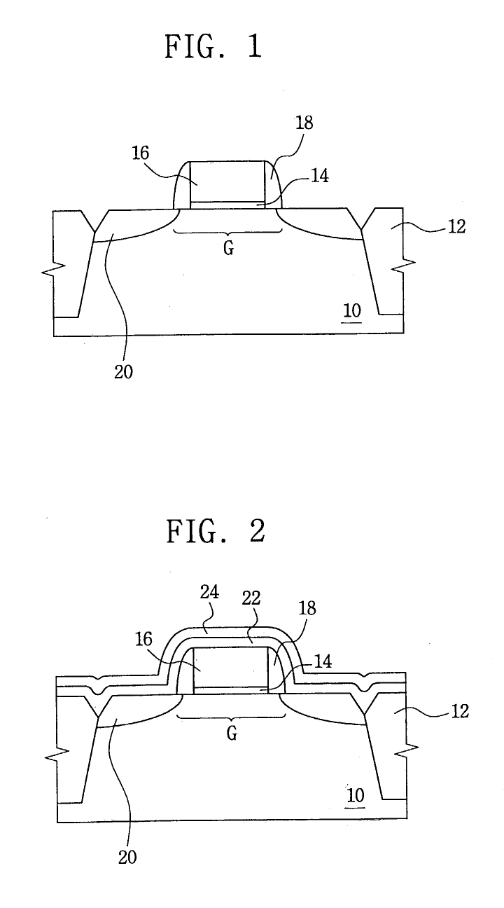

FIGS. 1 to 4 show in sequence a semiconductor device fabricating method using a salicide process. The fabricating method is divided into four steps, for ease of explanation.

In a “first step,” a cleaning process is performed on a gate electrode and source/drain regions of a semiconductor substrate as shown in FIG. 1, before a salicide process to be executed later.

Referring to FIG. 1 the “first step” includes procedures of sequentially accumulating a gate oxide film 14 and a gate conductive film 16 on a semiconductor substrate 10, and forming a gate region through a general photoetching. Subsequently, an oxide film is formed, and is etched back so as to form a spacer 18 existing only on both side walls of the gate regions and to form a gate electrode G. Through a use of the gate electrode G as a mask, ions, as a conductive material, are injected to the semiconductor substrate 10, to thus form source/drain regions 20 on a region overlapped with the gate electrode G.

After the gate electrode G and the source/drain regions 20 are formed on the semiconductor substrate 10, a cleaning process is performed before the salicide process is executed. This cleaning process is to remove a natural oxide film that is formed in the midst of the process on the gate electrode G and the source/drain regions 20 on which the silicide film will be formed, and utilizes only a wet etching. In this wet etching, the semiconductor substrate 10 provided with the gate electrode G and the source/drain regions 20 is soaked for 580-620 seconds into a mixed solution of about 120° C. with a ratio of 6:1 for H₂SO₄ and H₂0₂. Then, the substrate 10 is again soaked in an etching solution diluted by a ratio of 100:1 of HF and H₂O, preferably for about 200˜300 seconds. Herewith, an etching time of about 250 seconds has the most prominent cleaning effect.

In a conventional wet etching, an etching for about 100 seconds was performed, but the cleaning effect was lacking. Thus an RF sputtering etching was performed as an additional step. However, this conventional technique caused problems due to the RF sputtering etching. Meanwhile, in the presently disclosed process, only the wet etching is executed under the above-described conditions, to thereby overcome a decrease in the cleaning effect caused when the RF sputtering etching of the conventional technique is not executed, and to also restrain an occurrence of particles caused when the RF sputtering etching is executed. Accordingly, a defect in forming a cobalt silicide film can be prevented, and the cobalt silicide film can be formed with a desired thickness.

Beneficially, since an RF sputtering process is not performed, the cleaning process on the semiconductor substrate can be performed entirely within a single chamber. Thus, this process can prevent the production of particles that may be caused due when a semiconductor substrate is moved between chambers while cleaning the substrate.

In a second stage, as shown in FIG. 2, a cobalt film 22 and a TiN film 24 are formed on an overall surface of the semiconductor substrate 10 having the gate electrode G and the source/drain regions 20 after the completed cleaning process. Describing the procedures in detail, when the cleaning process on the semiconductor substrate 10 having the gate electrode G and the source/drain regions 20 is completed, the cobalt film 22 as a high melting point metal is deposited on an entire surface of the semiconductor substrate 10 having the gate electrode G and the source/drain regions 20. This cobalt film 22 has a thickness of about 150 Å and is formed through a general deposition method, e.g., the sputtering method, etc.

Next, in the same reaction chamber, the TiN film 24 as one capping film is deposited on the cobalt film 22. The TiN film 24 is deposited with a thickness of about 100 Å by using gas, mixed with a ratio of 1:0.1˜1:2 in Ar and N₂ gas. Herewith, in such a deposited TiN film 24, a Ti-rich TiN film having abundant titanium in comparison with a general TiN film is used, so as to subsequently more stably form a cobalt silicide film with a desired thickness.

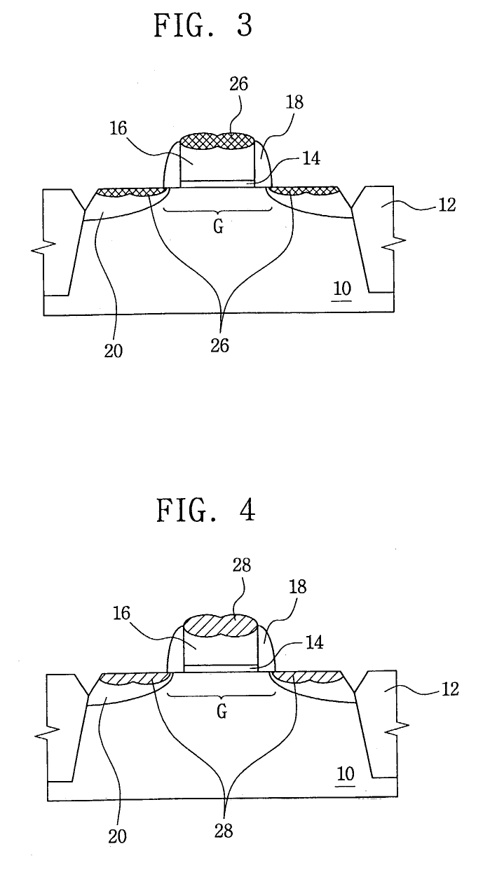

Referring to FIG. 3, in a third stage, when a first heat process is executed subsequently to the second stage mentioned above, a cobalt mono silicide (CoSi) film 26 is formed, and the remaining cobalt film 22 and the TiN film 24 in a region where the CoSi film 26 is not formed are removed. Describing in detail the procedures, when the first heat process is performed after the second step, the CoSi film 26 is formed on the gate electrode G and the source/drain regions. Herewith, the executed first heat process is performed through a rapid thermal salicidation (RTS) at a low temperature of about 450˜500° C. At this time, the Ti-rich TiN film 24 formed on the cobalt film 22 acts as a capping layer, so as to prevent a diffusion of the cobalt film 22 in the heat process and to control a reaction speed in the formation of the CoSi film 26.

Meanwhile, the cobalt film 22 reacts with conductive material, namely, the gate conductive layer and conductive material having received an ion injection, which constitutes the gate electrode G and the source/drain regions 20, during the first heat process, to thus form the CoSi film 26. Next, after the first heat process, the cobalt film 22 and the TiN film 24 in a region where the CoSi film 26 is not formed, namely, the region excluding the upper part of gate electrode G's and the source/drain regions, are removed by an etching. At this time, the etching solution that is utilized contains sulfuric acid and ammonium hydroxide etc.

With reference to FIG. 4, in a fourth stage subsequent to the third stage, when a second heat process is executed on the CoSi film 26, a cobalt di-silicide (CoSi₂) film 28 is formed to then complete the salicide process.

Explaining the procedures in detail, after the third stage, the second heat process is executed to thus form the CoSi₂ 28 from the CoSi film 26. Herewith, the executed second heat process is performed through the RTS process at a high temperature of about 750˜900° C. Therefore, the CoSi film 26 forms the CoSi₂ film 28 which is more stabile and has a lower inherent resistance, and then the salicide process is complete.

As described above, a process condition of a wet etching is reinforced, to thus remove a natural oxide film. As a result, a decrease in the effectiveness of a cleaning process, when the RF sputtering etching of a conventional technique is not performed, can be prevented, and a defect in forming a cobalt salicide film in a subsequent process can be prevented. In addition, a Ti-rich TiN film is formed as a capping film, to whereby form a cobalt salicide film with a desired thickness, more stably.

As mentioned above, in accordance with the present invention, only a wet etching is used to restrain an occurrence of particles, thereby preventing a defect in forming a cobalt silicide film and enabling the cobalt silicide film to be formed to a desired thickness.

Additionally, a Ti-rich TiN film is formed as a capping film, to thus, more stably, form the cobalt silicide film to a desired thickness.

Finally, although the present invention was described in detail above in connection with preferred embodiments thereof, the scope of the invention is not so limited. Rather, various changes and modifications of the preferred embodiments, as will become apparent to those of ordinary skill in the art, are seen to be within the true spirit and scope of the invention as defined by the appended claims.

What is claimed is:

1. A method of fabricating a semiconductor device through a salicide process, said method comprising:
forming a gate electrode and source/drain regions on a semiconductor substrate;
cleaning the semiconductor substrate by performing only a wet etching without any RF sputtering;
forming sequentially on the semiconductor substrate a high melting point metal film and a capping film;
forming a mono-silicide film on the gate electrode and the source/drain regions through a first heat process;
removing the high melting point metal film and the capping film from a region of the semiconductor substrate excluding a region where the mono-silicide film is formed; and
forming a di-silicide film through a second heat process.

2. The method of claim 1, wherein said wet etching removes a natural oxide film formed on the gate electrode and the source/drain regions.

3. The method of claim 1 or 2, wherein said wet etching is performed for about 200˜300 seconds.

4. The method of claim 1, wherein said capping film is a Ti-rich TiN film.

5. The method of claim 1, wherein said high melting point metal film is a cobalt film.

6. The method of claim 1, wherein said first heat process is executed through a rapid thermal salicidation (RTS) at a temperature of about 450˜500° C.

7. The method of claim 1, wherein said second heat process is executed through the RTS at a temperature of about 750˜900 C.

8. The method of claim 1, wherein said step of removing the high melting point metal film and the capping film is executed through an etching.

9. The method of claim 1, wherein the wet etching comprises soaking the semiconductor substrate for 580-620 seconds in a mixed solution of about 120° C. with a ratio of 6:1 for H₂SO₄ and H₂O₂, and then soaking the semiconductor substrate for 200-300 seconds in an etching solution diluted by a ratio of 100:1 of HF and H₂O.

10. The method of claim 1, wherein the semiconductor substrate is cleaned entirely within one chamber.

11. A method of fabricating a semiconductor device through a salicide process on a gate electrode and source/drain regions formed on a semiconductor substrate, said method comprising:
cleaning the gate electrode and the source/drain regions by executing only a wet etching; and
subsequently executing a process of forming a silicide film on the gate electrode and the source/drain regions.

12. The method of claim 11, wherein the process of forming a silicide film on the gate electrode and the source/drain regions includes:
forming a high melting point metal film on the semiconductor substrate;
forming a capping film on an upper part of the high melting point metal film.

12. The method of claim 11, wherein forming the capping film includes forming a Ti-rich TiN film on the upper part of the high melting point metal film.

13. The method of claim 11, further comprising forming a mono-silicide film on the gate electrode and the source/drain regions through a first heat process executed on the semiconductor substrate.

14. The method of claim 11, wherein the wet etching comprises soaking the semiconductor substrate for 580-620 seconds in a mixed solution of about 120° C. with a ratio of 6:1 for H₂SO₄ and H₂O₂, and then soaking the semiconductor substrate for 200-300 seconds in an etching solution diluted by a ratio of 100:1 of HF and H₂O.

15. The method of claim 11, wherein the semiconductor substrate is cleaned entirely within one chamber.

16. A method of fabricating a semiconductor device through a salicide process, comprising:
forming a high melting point metal film on an entire surface of a semiconductor substrate on which a gate electrode and source/drain regions are formed;
forming a capping film on an upper part of the high melting point metal film; and
subsequently performing a heat process to form a silicide film only on the gate electrode and the source/drain regions.

17. The method of claim 16, wherein forming the capping film includes forming a Ti-rich TiN film on the upper part of the high melting point metal film.

18. The method of claim 16, wherein the heat process includes heating the semiconductor substrate a first time at a temperature of about 450˜500° C., and subsequently heating the semiconductor substrate a second time at a temperature of about 750˜900° C.

19. The method of claim 1, further comprising cleaning the gate electrode and the source/drain regions by executing only a wet etching prior to forming the high melting point metal film.

20. The method of claim 19, wherein the semiconductor substrate is cleaned entirely within one chamber.
